(19) United States
(12) Patent Application Publication
(10) Pub. No.: US 2012/0074476 A1
(43) Pub. Date: Mar. 29, 2012

(54) INTEGRATED CIRCUIT

(75) Inventors: Yoshiyuki Kondo, Yokohama-Shi (JP); Shigeru Kawanaka, Yokohama-Shi (JP)

(73) Assignee: KABUSHIKI KAISHA TOSHIBA, Tokyo (JP)

(21) Appl. No.: 13/230,077

(22) Filed: Sep. 12, 2011

(30) Foreign Application Priority Data
Sep. 24, 2010 (JP) 2010-213585

(51) Int. Cl. H01L 27/088

(52) U.S. Cl. 257/295; 257/E27.06

(57) ABSTRACT

In accordance with an embodiment, an integrated circuit includes a circuit in which first and second spin transistors are connected in series. The first spin transistor has a first node and a second node that are equal to each other in magnetization direction. The second spin transistor has a third node and a fourth node that are opposite to each other in magnetization direction. The second node and the fourth node are electrically connected to each other.

### CROSS REFERENCE TO RELATED APPLICATIONS

This application is based upon and claims the benefit of priority from the prior Japanese Patent Application No. 2010-213585, filed on Sep. 24, 2010, the entire contents of which are incorporated herein by reference.

### FIELD

Embodiments described herein relate generally to an integrated circuit.

### BACKGROUND

Recently, there has been known a spin FET. The spin FET uses, as a channel, a two dimensional electron gas (2DEG) induced at the interface of a modulation-doped structure comprising, for example, an InAlAs/InGaAs heterojunction, and uses a ferromagnetic body for a source and a drain.

### BRIEF DESCRIPTION OF THE DRAWINGS

FIG. 1A is a schematic diagram of an integrated circuit that uses two spin transistors according to a first embodiment;

FIG. 1B is a schematic diagram illustrating the basic operation of the spin transistor;

FIG. 1C is a schematic diagram concerning a relative angle between the majority spin direction of a drain region and a spin deflection vector of an electron in a 2DEG channel;

FIG. 2 is a schematic diagram of an inverter circuit that uses two spin transistors according to the first embodiment;

FIG. 3A is a schematic diagram concerning the operation of a first spin transistor when V_{low} is input as Vᵢₙ according to the first embodiment;

FIG. 3B is a schematic diagram concerning the operation of a second spin transistor when V_{low} is input as Vᵢₙ;

FIG. 3C is a schematic diagram concerning the operation of the first spin transistor when V_{high} is input as Vᵢₙ;

FIG. 3D is a schematic diagram concerning the operation of the second spin transistor when V_{high} is input as Vᵢₙ;

FIG. 4 is a schematic diagram of an integrated circuit according to a second embodiment;

FIG. 5A is a schematic diagram of an integrated circuit according to a third embodiment;

FIG. 5B is a top view of the integrated circuit shown in FIG. 5A;

FIG. 6A to FIG. 6O are essential part sectional views showing a process of manufacturing the integrated circuit according to the third embodiment;

FIG. 7 is a schematic diagram of magnetization curves of magnetic metals according to the third embodiment;

FIG. 8A is a schematic diagram of an integrated circuit according to a fourth embodiment;

FIG. 8B is a schematic diagram of magnetization curves of a first magnetic metal and a second magnetic metal;

FIG. 9 is a schematic diagram of an integrated circuit according to a fifth embodiment;

FIG. 10A is a schematic diagram of a NAND circuit according to a sixth embodiment;

FIG. 10B is a logical operation table of the NAND circuit;

FIG. 11A is a schematic diagram of a NOR circuit according to a seventh embodiment; and

FIG. 11B is a logical operation table of the NOR circuit.

### DETAILED DESCRIPTION

In accordance with an embodiment, an integrated circuit includes a circuit in which first and second spin transistors are connected in series. The first spin transistor has a first node and a second node that are equal to each other in magnetization direction. The second spin transistor has a third node and a fourth node that are opposite to each other in magnetization direction. The second node and the fourth node are electrically connected to each other.

Embodiments will now be explained with reference to the accompanying drawings.

In a spin FET, a carrier moves through a 2DEG channel. The precession of a spin of the carrier moving through the 2DEG channel is controlled by Rashba effect. In the spin FET, when the direction of a spin deflection vector of the carrier at a drain end corresponds to the direction of a metallic spin band of a drain, a large number of carriers are conducted in a drain region. In the spin FET, when the direction of the spin deflection vector of the carrier corresponds to the direction of an insulator-like spin band, few carriers conduct the drain. It has heretofore been impossible to use the spin FET to produce a circuit equivalent to a conventional logical operation circuit comprising a MOSFET.

### First Embodiment

(Configuration of Integrated Circuit)

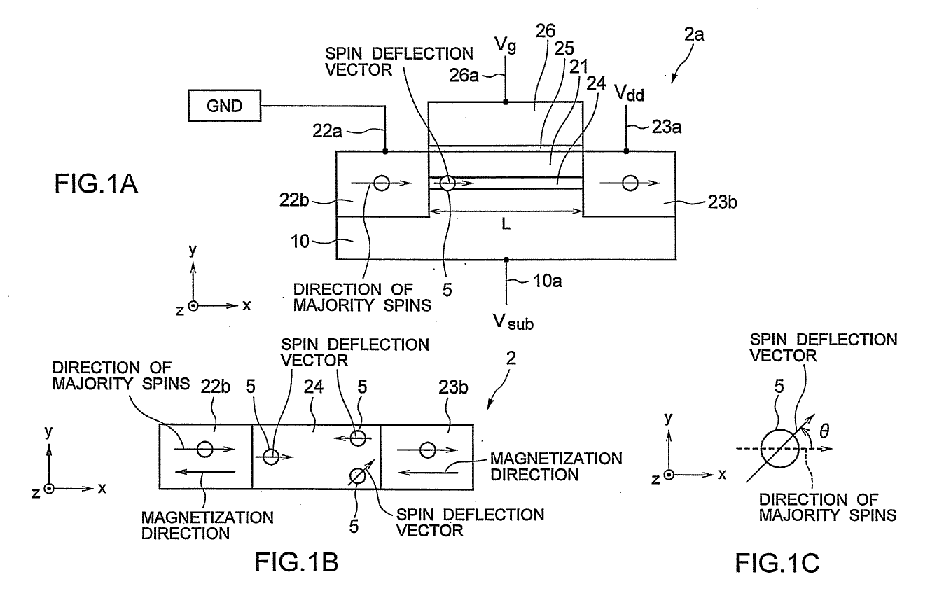

FIG. 1A is a schematic diagram of a spin transistor according to the first embodiment. FIG. 1B is a schematic diagram illustrating the basic operation of the spin transistor. FIG. 1C is a schematic diagram concerning a relative angle between the direction of majority spins of a magnetic body of a drain region and a spin deflection vector of an electron in a channel. An x-y-z coordinate system indicated in each of the drawings is, for example, a rectangular coordinate system. In particular, the direction of an effective magnetic field resulting from Rashba effect is defined as a z axis.

Hereinafter, arrows in a source region 22b and a drain region 23b of a spin transistor 2a indicate the directions of majority spins in each region. The direction of the majority spins indicates the direction of the angular momentum of the spins of majority electrons in the magnetic body. Moreover, when particles having magnetism are electrons, the direction of the majority spins is opposite to the magnetization direction of a magnetic body. Arrows in regions shown in FIG. 1B indicate a magnetization direction. Hereinafter, unless otherwise stated, the majority spin direction is used for explanation instead of the magnetization direction.

Further, hereinafter, the arrow of an electron 5 indicates the deflection vector of the spin of the electron 5.

Still further, while the flow (spin current) of the electron 5 which is a carrier is mainly described below, it should be noted that the flow direction of the electron 5 which is a carrier is opposite to the flow direction of a current. Therefore, the electron (spin current) as a carrier travels from a low potential side (V_{low}) to a high potential side (V_{high}), whereas the current runs from the high potential side (V_{high}) to the low potential side (V_{low}).

As shown in FIG. 1A, the spin transistor 2a is formed on, for example, a semiconductor substrate 10. The spin transistor 2a generally comprises, for example, a semiconductor cap layer 21, a source region 22b as a first node, a drain region 23b as a second node, a 2DEG channel 24, a gate insulating film 25, and a gate electrode 26 as a first gate electrode.

The semiconductor substrate 10 has a double heterostructure in which In₁₋ₓAlₓAs, In_{1-y}Ga_{y}As, and In₁₋ₓAlₓAs are stacked on an InP substrate in order by, for example, a molecular beam epitaxy method (MBE). While a large number of combinations of In₁₋ₓAlₓAs and In_{1-y}Ga_{y}As are possible depending on the mixing ratio, x=0.48 and y=0.47 in the present embodiment. Thus, hereinafter, unless otherwise stated, InAlAS indicates In_{0.52}Al_{0.48}As, and InGaAs indicates In_{0.53}Ga_{0.47}As. The spin transistor 2a has, for example, a terminal 10a under the gate electrode 26. A substrate potential V_{sub} is applied to the terminal 10a.

The semiconductor cap layer 21 uses, for example, InAlAs in the upper layer of the semiconductor substrate 10. The semiconductor cap layer 21 is, for example, Schottky-connected to the source region 22b and the drain region 23b. Here, in the 2DEG channel 24, an InGaAs layer in the quantum well structure of InAlAs/InGaAs/InAlAs serves as a 2DEG channel. When, for example, the semiconductor substrate 10 has a heterostructure in which InAlAs/InGaAs are stacked, the 2DEG channel 24 is formed at an interface between InAlAs and InGaAs.

The source region 22b is formed, for example, by removing InAlAs, InGaAs, and part of InAlAs under InGaAs in the semiconductor substrate 10. The source region 22b has, for example, a terminal 22a. This terminal 22a is, for example, grounded (GND).

The drain region 23b is formed, for example, by removing InAlAs, InGaAs, and part of InAlAs under InGaAs in the semiconductor substrate 10. The drain region 23b has, for example, a terminal 23a. A power supply voltage V_{dd} (>0) is supplied to this terminal 23a from a power supply circuit.

The source region 22b and the drain region 23b are formed by use of, for example, a high spin deflection material. The high spin deflection material has high spin polarizability (spin deflection factor) of electrons therein and can inject a large number of electrons having a uniform spin direction into the 2DEG channel. A ferromagnetic metal and a half metal ferromagnetic body, for example, are used as the high spin deflection materials.

When the ferromagnetic metal is used as the high spin deflection material, an Fe-based metal, a Co-based metal, and an Ni-based metal, for example, are used as the ferromagnetic metals. Here, the source region 22b and the drain region 23b are preferably made of, for example, a ferromagnetic body which is highly consistent with a group III-V semiconductor and which has a Curie temperature equal to or more than a room temperature (e.g. 300 K) and which has a wide band gap in the vicinity of a Fermi level E_{F} regarding the energy state of one spin. Suitable as such a ferromagnetic body is, for example, a half metal ferromagnetic body having a band structure in which the Fermi level E_{F} traverses one spin band (metallic spin band) and traverses the band gap in the other spin band (insulator-like spin band). That is, when the half metal ferromagnetic body having the above-mentioned band structure is used, a carrier having a theoretically 100% spin polarizability can be injected. This half metal ferromagnetic body comprises, for example, CrO₂, Fe₂O₃, Ga₁₋ₓMnₓAs, In₁₋ₓMnₓAs, Ge₁₋ₓMnₓ, LaSrMnO₄, or a Heuslar alloy. As the Heuslar alloy, Co₂MnAi, Co₂MnGe, Co₂MnSi, Co₂CrAl, Co₂FeAl, or CoMnGa, for example, is used. The channel length of the 2DEG channel 24 is, for example, L. The electron 5 travels through the 2DEG channel 24 from the source region 22b to the drain region 23b.

Here, when the electron 5 travels to the drain region 23b through the 2DEG channel 24, a spin orbit interaction called Rashba effect proportional to the intensity of an electric field in a y-axis direction emerges. As a result, an effective magnetic field is generated in a z-axis direction, and the spin in the electron 5 is influenced by this magnetic field. As shown in FIG. 1C, the spin of the electron 5 precesses around the z axis. The precession is performed in a direction in which a relative angle θ between a dotted line shown in FIG. 1C and an arrow indicating the direction of the deflection vector of the spin increases, that is, the precession is performed counterclockwise. The change of the relative angle θ caused by the precession is dependent on a Rashba parameter α and the channel length L. The Rashba parameter α here is an amount that indicates the magnitude of the Rashba effect. The Rashba parameter a also changes with a gate voltage V_{g}, and this change can be used to control the relative angle θ with the majority spin direction of the drain region 23b in the vicinity of the drain region within the 2DEG channel 24. Moreover, the Rashba parameter α is also dependent on the material of the 2DEG channel 24. Therefore, the Rashba effect can be controlled by changing one of the layers that constitute the stack structure of the semiconductor substrate 10. The dotted line shown in FIG. 1C indicates the direction parallel to the direction of the majority spins of the drain region 23b.

As shown in FIG. 1B, for example, the electron 5 is injected into the 2DEG channel 24 from the source region 22b in a spin-polarized condition, that is, in a condition in which the spin direction is uniform. The injected electron 5 precesses due to, for example, the Rashba effect, and penetrates or is reflected depending on the spin state when the electron 5 has reached the drain region 23b.

For example, as shown in FIG. 1B, when the spin deflection vector is opposite to the direction of the majority spins of the drain region 23b, that is, is in the negative direction of the x axis in the drawing, the electron 5 is reflected at the border between the 2DEG channel 24 and the drain region 23b. On the other hand, for example, as shown in FIG. 1B, when the spin deflection vector is not opposite to the direction of the majority spins of the drain region 23b, the electron 5 penetrates the border between the 2DEG channel 24 and the drain region 23b. An integrated circuit that uses the above-mentioned spin transistor is described below. It is to be noted that parts equivalent in configuration and function to those in the above-mentioned spin transistor 2a are provided with the same reference signs and are not described.

(Configuration of Integrated Circuit)

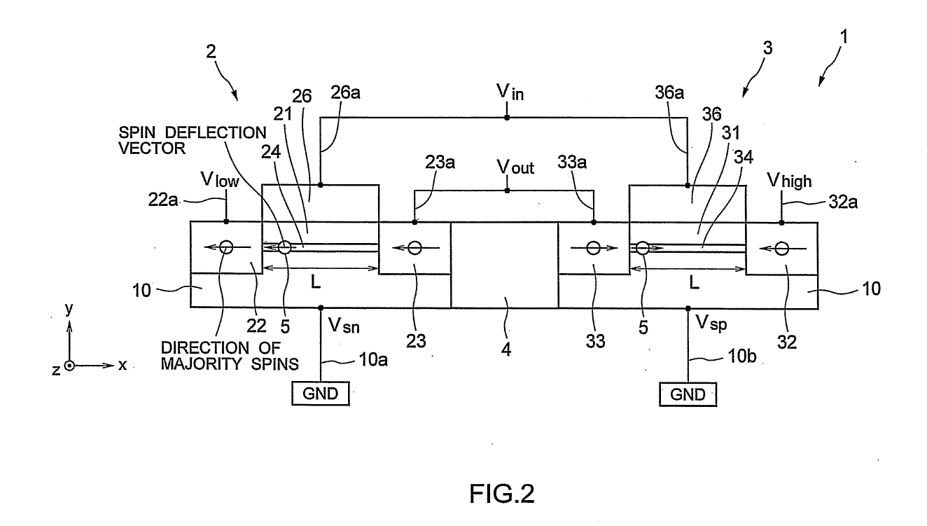

FIG. 2 is a schematic diagram of an inverter circuit that uses two spin transistors according to the first embodiment.

Hereinafter, arrows with circular marks in a V_{low} node 22 and an output node 23 of a first spin transistor 2 and in a V_{high} node 32 and an output node 33 of a second spin transistor 3 indicate the majority spin directions of the respective nodes.

An integrated circuit 1 is, for example, a logical operation circuit that uses the first and second two spin transistors 2 and 3. This logical operation circuit is, for example, an inverter circuit. As shown in FIG. 2, in the integrated circuit 1, an element isolation region 4 for electrically isolating the first and second spin transistors 2 and 3, for example, is formed between the first and second spin transistors 2 and 3. This element isolation region 4 comprises, for example, SiO₂.

As shown in FIG. 2, the first spin transistor 2 is formed on, for example, a semiconductor substrate 10. The first spin transistor 2 generally comprises, for example, a semiconductor cap layer 21, the V_{low} node 22 as a first node, the output node 23 as a second node, a 2DEG channel 24, and a gate electrode 26 as a first gate electrode.

The first spin transistor 2 has, for example, a terminal 10a under the gate electrode 26. This terminal 10a is grounded (GND). Thus, a substrate potential Vₛₙ of the first spin transistor 2 is, by way of example, 0 V.

The semiconductor cap layer 21 is, for example, InAlAs in the upper layer of the semiconductor substrate 10. In the present embodiment, the semiconductor cap layer 21 is a layer that includes a gate insulating film. The semiconductor cap layer 21 is, for example, Schottky-connected to the V_{low} node 22 and the output node 23. Here, in the 2DEG channel 24, an InGaAs layer in the quantum well structure of InAlAs/InGaAs/InAlAs serves as a 2DEG channel. When, for example, the semiconductor substrate 10 has a heterostructure in which InAlAs/InGaAs are stacked, the 2DEG channel 24 is formed at an interface between InAlAs and InGaAs.

The V_{low} node 22 is formed, for example, by removing InAlAs, InGaAs, and part of InAlAs under InGaAs in the semiconductor substrate 10. The V_{low} node 22 has, for example, a terminal 22a. For example, a power supply voltage V_{low} as a first voltage is supplied to this terminal 22a from a power supply circuit.

The output node 23 is formed, for example, by removing InAlAs, InGaAs, and part of InAlAs under InGaAs in the semiconductor substrate 10. The output node 23 has, for example, a terminal 23a. This terminal 23a is connected to a terminal 33a of the later-described output node 33 of the second spin transistor 3. That is, output node 23 is electrically connected to the output node 33. The integrated circuit 1 is a circuit in which the first spin transistor 2 and the second spin transistor 3 are connected in series between the power supply voltage V_{low} and a power supply voltage V_{high} as a second voltage.

As shown in FIG. 2, the V_{low} node 22 and the output node 23 have the same majority spin direction. That is, the V_{low} node 22 and the output node 23 have the same magnetization direction.

The V_{low} node 22 and the output node 23 are formed by use of, for example, a high spin deflection material. A ferromagnetic metal and a half metal ferromagnetic body, for example, are used as the high spin deflection materials.

The V_{low} node 22, the output node 23, the later-described V_{high} node 32, and the output node 33 according to the present embodiment are formed by use of, for example, Co₂MnSi. The channel length of the 2DEG channel 24 is, for example, L. The electron 5 travels through the 2DEG channel 24 from the V_{low} node 22 to the output node 23.

The gate electrode 26 is formed on, for example, the semiconductor cap layer 21. The gate electrode 26 is made of, for example, polycrystalline Si. The gate electrode 26 has, for example, a terminal 26a. This terminal 26a is connected to, for example, a later-described terminal 36a of a second gate electrode 36 of the second spin transistor 3. A digital signal Vᵢₙ is input to the terminal 26a. That is, the gate electrode 26 is electrically connected to the second gate electrode 36.

As shown in FIG. 2, the second spin transistor 3 is formed on, for example, the semiconductor substrate 10. The second spin transistor 3 generally comprises, for example, a semiconductor cap layer 31, a V_{high} node 32 as a third node, an output node 33 as a fourth node, a 2DEG channel 34, and a gate electrode 36 as a second gate electrode.

The second spin transistor 3 has, for example, a terminal 10b under the gate electrode 36. This terminal 10b is grounded (GND). Thus, a substrate potential Vₛₚ of the second spin transistor 3 is, by way of example, 0 V.

The semiconductor cap layer 31 is substantially the same as, for example, the semiconductor cap layer 21 of the first spin transistor 2. The semiconductor cap layer 31 is, for example, Schottky-connected to the V_{high} node 32 and the output node 33. Here, in the 2DEG channel 34, an InGaAs layer in the quantum well structure of InAlAs/InGaAs/InAlAs serves as a 2DEG channel. When, for example, the semiconductor substrate 10 has a heterostructure in which InAlAs/InGaAs are stacked, the 2DEG channel 34 is formed at an interface between InAlAs and InGaAs.

The V_{high} node 32 and the output node 33 are formed, for example, by removing InAlAs, InGaAs, and part of InAlAs under InGaAs in the semiconductor substrate 10. The V_{high} node 32 and the output node 33 are formed by using, for example, the same material as that of the V_{low} node 22 and the output node 23 of the first spin transistor 2. The majority spin directions of the V_{high} node 32 and the output node 33 of the second spin transistor 3 are opposite to each other.

The V_{high} node 32 has, for example, a terminal 32a. The power supply voltage V_{high} is supplied to this terminal 32a, for example, from a power supply circuit. The output node 33 has, for example, the terminal 33a.

The 2DEG channel 34 has the same channel length L as the first spin transistor 2. An electron 5 travels through the 2DEG channel 34 from the output node 33 to the V_{high} node 32.

The gate electrode 36 is formed on, for example, the semiconductor cap layer 31. The gate electrode 36 is made of, for example, the same material as the gate electrode 26 of the first spin transistor 2. The gate electrode 36 has, for example, the terminal 36a. A digital signal Vᵢₙ, for example, is input to the terminal 36a.

Here, the integrated circuit 1 is an inverter circuit which outputs the digital signal V_{high} as Vₒᵤₜ when the digital signal V_{low} is input as Vᵢₙ and which outputs the digital signal V_{low} as Vₒᵤₜ when the digital signal V_{high} is input as Vᵢₙ.

The operation of the integrated circuit according to the present embodiment is described below.

(Operation)

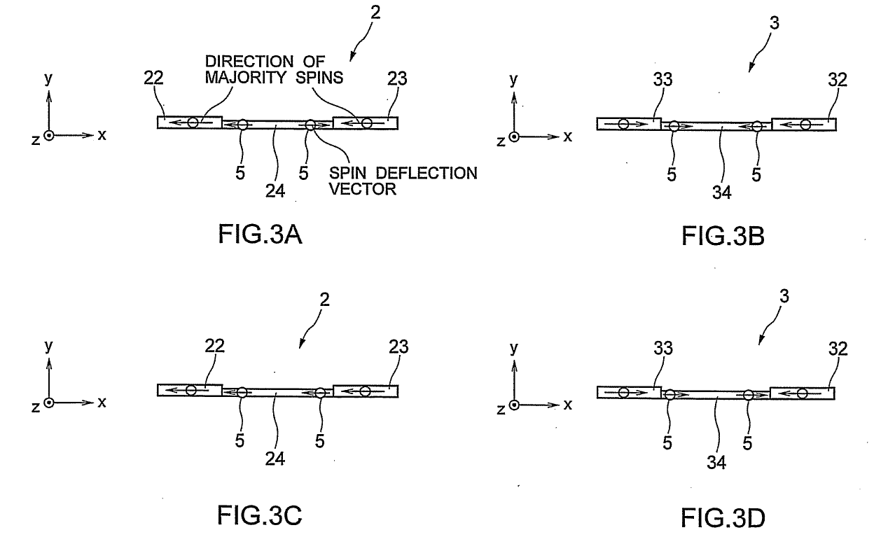

FIG. 3A is a schematic diagram concerning the operation of the first spin transistor when V_{low} is input as Vᵢₙ according to the first embodiment. FIG. 3B is a schematic diagram concerning the operation of the second spin transistor when V_{low} is input as Vᵢₙ. FIG. 3C is a schematic diagram concerning the operation of the first spin transistor when V_{high} is input as Vᵢₙ. FIG. 3D is a schematic diagram concerning the operation of the second spin transistor when V_{high} is input as Vᵢₙ.

(When Vᵢₙ=V_{low})

First, V_{low} is input as Vᵢₙ to the gate electrode 26 of the first spin transistor 2 and to the gate electrode 36 of the second spin transistor 3.

As shown in FIG. 3A, a spin-polarized electron 5 is injected into the 2DEG channel 24 from the V_{low} node 22 of the first spin transistor 2.

As shown in FIG. 3A, this electron 5 precesses, for example, at an angle π around the z axis due to an effective magnetic field in the 2DEG channel 24, and reaches the border between the 2DEG channel 24 and the output node 23.

The electron 5 which has reached the border has a spin direction opposite to the majority spin direction of the output node 23, and is therefore reflected at the border.

On the other hand, as shown in FIG. 3B, a spin-polarized electron 5 is injected into the 2DEG channel 34 from the output node 33 of the second spin transistor 3.

As shown in FIG. 3B, this electron 5 precesses, for example, at an angle π around the z axis due to an effective magnetic field in the 2DEG channel 34, and reaches the border between the 2DEG channel 34 and the V_{high} node 32.

The majority spin direction of the electron 5 which has reached the border is the same as the majority spin direction of the V_{high} node 32. This is due to the fact that the majority spin direction of the V_{high} node 32 differs from the majority spin direction of the output node 33 by an angle π. Therefore, the electron 5 penetrates the border between the 2DEG channel 34 and the V_{high} node 32. That is, the potential of the output node 33 is V_{high}.

Accordingly, in the integrated circuit 1, when Vᵢₙ=V_{low}, no current runs through the first spin transistor 2, and a current runs through the second spin transistor 3, so that V_{high} input to the V_{high} node 32 of the second spin transistor 3 is output from Vₒᵤₜ.

(When Vᵢₙ=V_{high})

First, V_{high} is input as Vᵢₙ to the gate electrode 26 of the first spin transistor 2 and to the gate electrode 36 of the second spin transistor 3.

As shown in FIG. 3C, a spin-polarized electron 5 is injected into the 2DEG channel 24 from the V_{low} node 22 of the first spin transistor 2.

As shown in FIG. 3C, this electron 5 precesses, for example, at an angle 2π around the z axis due to a magnetic field in the 2DEG channel 24, and reaches the border between the 2DEG channel 24 and the output node 23.

The electron 5 which has reached the border has a spin direction that is the same as the majority spin direction of the output node 23, and therefore penetrates the border. That is, the potential of the output node 23 is V_{low}.

On the other hand, as shown in FIG. 3D, a spin-polarized electron 5 is injected into the 2DEG channel 34 from the output node 33 of the second spin transistor 3.

As shown in FIG. 3D, this electron 5 precesses, for example, at an angle 2π around the z axis due to an effective magnetic field in the 2DEG channel 34, and reaches the border between the 2DEG channel 34 and the V_{high} node 32.

The electron 5 which has reached the border has a spin direction opposite to the majority spin direction of the V_{high} node 32, and is therefore reflected at the border.

Accordingly, in the integrated circuit 1, when Vᵢₙ=V_{high}, a current runs through the first spin transistor 2, and no current runs through the second spin transistor 3, so that V_{low} input to the V_{low} node 22 of the first spin transistor 2 is output from Vₒᵤₜ.

Thus, the integrated circuit 1 comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the First Embodiment

The integrated circuit 1 according to the first embodiment comprises an inverter circuit having the first spin transistor 2 and the second spin transistor 3 that are connected in series. The first spin transistor 2 comprises the V_{low} node 22 and the output node 23 equal to each other in magnetization direction. The second spin transistor 3 comprises the V_{high} node 32 and the output node 33 opposite to each other in magnetization direction. Therefore, as compared with an inverter circuit which comprises a complementary metal oxide semiconductor (CMOS) transistor, there is no need for separate p-type and n-type transistors, leading to fewer manufacturing processes and reduced manufacturing costs.

### Second Embodiment

The second embodiment is different from the first embodiment in that the same node is used for the output node of a first spin transistor 2 and the output node of a second spin transistor 3. It is to be noted that in the following embodiments, parts equivalent in function and configuration to those in the first embodiment are provided with the same reference signs and are not described.

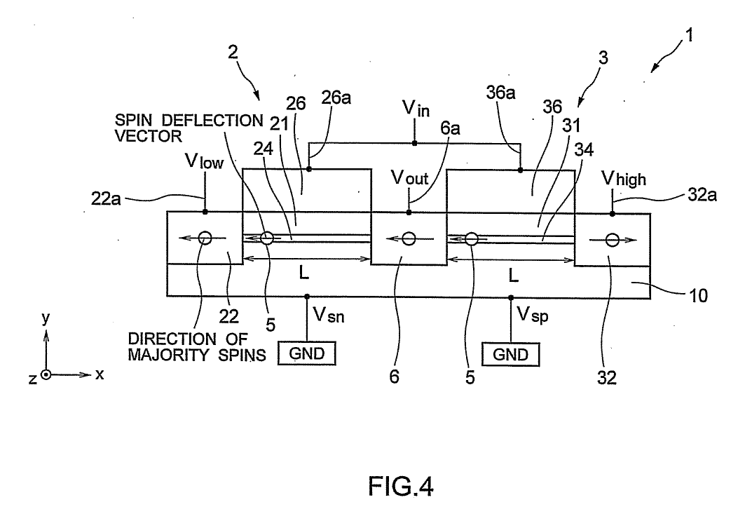

FIG. 4 is a schematic diagram of an integrated circuit according to the second embodiment. As shown in FIG. 4, in an integrated circuit 1, substrate potentials Vₛₙ and Vₛₚ are grounded, so that the element isolation region 4 in the first embodiment can be omitted. Thus, as shown in FIG. 4, the integrated circuit 1 comprises an output node 6 which allows the output node 23 of the first spin transistor 2 and the output node 33 of the second spin transistor 3 to be the same region.

This output node 6 is formed by using, for example, the same material as a V_{low} node 22 and a V_{high} node 32. The majority spin direction of V_{high} node 32 is opposite to the majority spin direction of the V_{low} node 22 and the output node 6.

The output node 6 has, for example, a terminal 6a. This terminal 6a outputs Vₒᵤₜ.

The operation of the integrated circuit 1 according to the present embodiment is described below.

(Operation)

(When Vᵢₙ=V_{low})

First, V_{low} is input as Vᵢₙ to a gate electrode 26 of the first spin transistor 2 and to a gate electrode 36 of the second spin transistor 3.

A spin-polarized electron 5 is injected into a 2DEG channel 24 from the V_{low} node 22 of the first spin transistor 2.

This electron 5 precesses, for example, at an angle π around the z axis due to an effective magnetic field in the 2DEG channel 24, and reaches the border between the 2DEG channel 24 and the output node 6.

The electron 5 which has reached the border has a spin direction opposite to the majority spin direction of the output node 6, and is therefore reflected at the border.

On the other hand, a spin-polarized electron 5 is injected into a 2DEG channel 34 from the output node 6 of the second spin transistor 3.

This electron 5 precesses, for example, at an angle π around the z axis due to an effective magnetic field in the 2DEG channel 34, and reaches the border between the 2DEG channel 34 and the V_{high} node 32.

The electron 5 which has reached the border has a spin direction that is the same as the majority spin direction of the V_{high} node 32, and therefore penetrates the border. That is, the potential of the output node 6 is V_{high}.

Accordingly, in the integrated circuit 1, when Vᵢₙ=V_{low}, no current runs through the first spin transistor 2, and a current runs through the second spin transistor 3, so that V_{high} is output from Vₒᵤₜ.

(When Vᵢₙ=V_{high})

First, V_{high} is input as Vᵢₙ to the gate electrode 26 of the first spin transistor 2 and to the gate electrode 36 of the second spin transistor 3.

A spin-polarized electron 5 is injected into the 2DEG channel 24 from the V_{low} node 22 of the first spin transistor 2.

This electron 5 precesses, for example, at an angle 2π around the z axis due to an effective magnetic field in the 2DEG channel 24, and reaches the border between the 2DEG channel 24 and the output node 6.

The electron 5 which has reached the border has a spin direction that is the same as the majority spin direction of the output node 6, and therefore penetrates the border.

On the other hand, a spin-polarized electron 5 is injected into the 2DEG channel 34 from the output node 6.

This electron 5 precesses, for example, at an angle 2π around the z axis due to an effective magnetic field in the 2DEG channel 34, and reaches the border between the 2DEG channel 34 and the V_{high} node 32.

The electron 5 which has reached the border has a spin direction opposite to the majority spin direction of the V_{high} node 32, and is therefore reflected at the border.

Accordingly, in the integrated circuit 1, when Vᵢₙ=V_{high}, a current runs through the first spin transistor 2, and no current runs through the second spin transistor 3, so that V_{low} is output from Vₒᵤₜ.

Thus, the integrated circuit 1 comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Second Embodiment

The integrated circuit 1 according to the second embodiment needs no element isolation region because the substrate potentials Vₛₙ and Vₛₚ are equal, and can therefore be placed in a smaller area as compared with an integrated circuit which requires an element isolation region.

### Third Embodiment

The third embodiment is different from the other embodiments described above in that one of magnetic body regions that is different in magnetization direction from the other (node) is made of a material different from the material of the other.

(Configuration of Integrated Circuit 1)

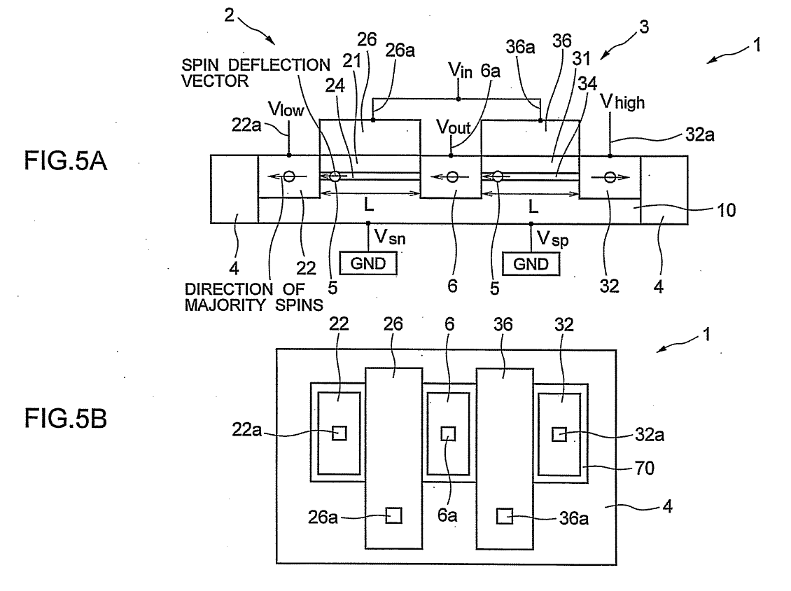

FIG. 5A is a schematic diagram of an integrated circuit according to the third embodiment. FIG. 5B is a top view of the integrated circuit.

In an integrated circuit 1 according to the present embodiment, a V_{high} node 32 shown in FIG. 5A is made of a material different from the material of a V_{low} node 22 and an output node 6. The internal strain of a magnetic body can be changed by, for example, reducing the content of an impurity or by changing its annealing conditions, and its coercive force can be changed. Thus, NiFe having a different doping ratio, by way of example, is used as the different material.

A method of manufacturing the integrated circuit 1 according to the present embodiment is described below.

(Integrated Circuit Manufacturing Method)

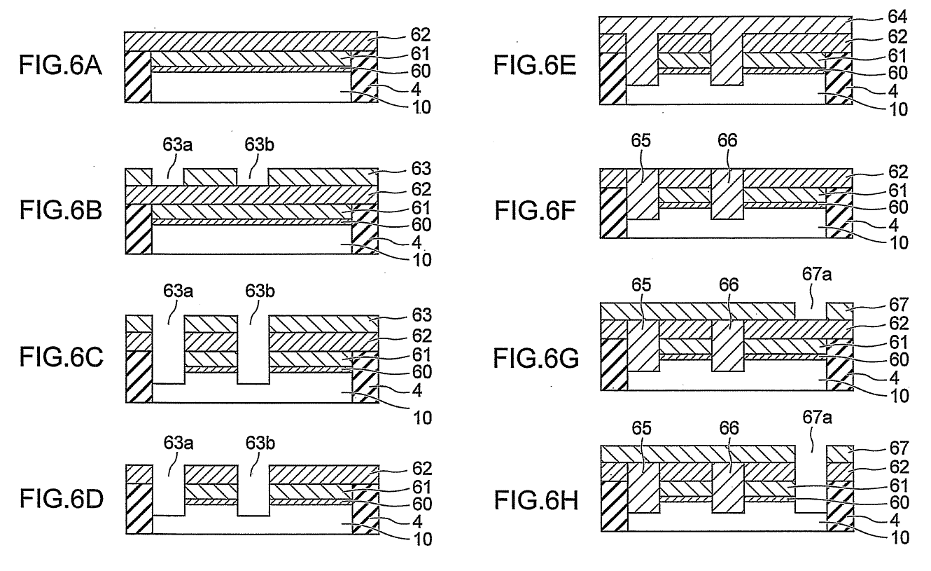

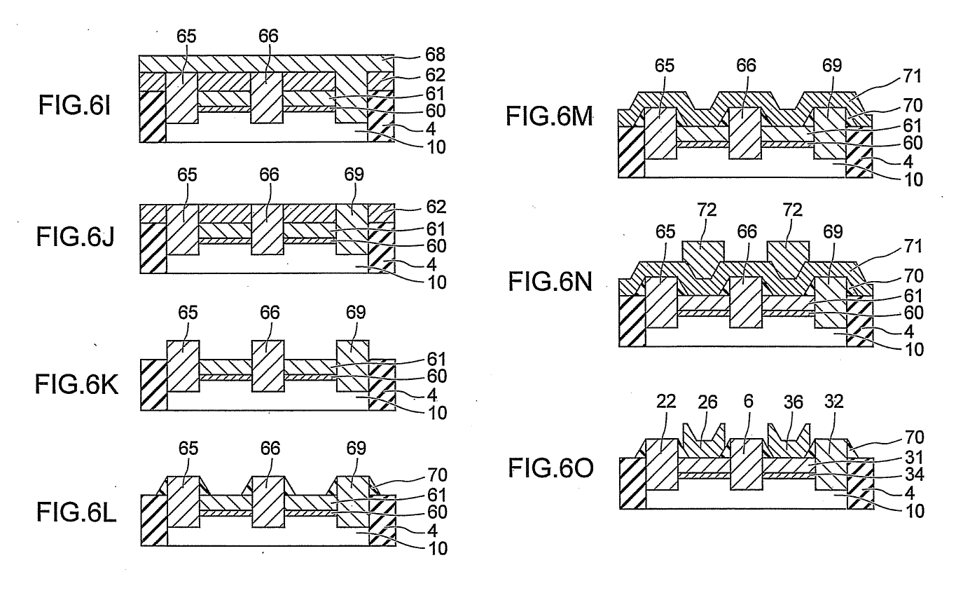

FIG. 6A to FIG. 6O are essential part sectional views showing the process of manufacturing the integrated circuit according to the third embodiment.

First, InAlAs, InGaAs, and InAlAs are stacked on an InP substrate in order, for example, by the molecular beam epitaxy method to form a semiconductor substrate 10. The InGaAs layer of the semiconductor substrate 10 serves as a 2DEG channel precursor layer 60. The upper InAlAs layer of the semiconductor substrate 10 serves as a semiconductor cap layer precursor layer 61.

As shown in FIG. 6A, an element isolation region 4 is then formed by a photolithography method and a reactive ion etching (RIE) method, and a protective film 62 is further formed.

As shown in FIG. 6B, a mask film 63 is then formed on the protective film 62 by, for example, the photolithography method and the RIE method. This mask film 63 has an opening 63a formed at a position corresponding to a V_{low} node 22 and an opening 63b formed at a position corresponding to an output node 6.

As shown in FIG. 6C, anisotropic etching is then carried out by, for example, the RIE method using the mask film 63 as a mask to remove the protective film 62 and the 2DEG channel precursor layer 60 in the opening 63a and the opening 63b and part of the semiconductor substrate 10.

As shown in FIG. 6D, the mask film 63 is then removed.

As shown in FIG. 6E, a first magnetic metal 64 is then formed in the opening 63a and the opening 63b and on the protective film 62 by, for example, a chemical vapor deposition (CVD) method. This first magnetic metal 64 is, for example, the above-mentioned Heuslar alloy.

As shown in FIG. 6F, planarization is then carried out by, for example, a chemical mechanical polishing (CMP) method to remove the first magnetic metal 64 on the protective film 62. As a result of the planarization, a magnetic region 65 comprising the first magnetic metal 64 is formed in the opening 63a, and a magnetic region 66 comprising the first magnetic metal 64 is formed in the opening 63b.

As shown in FIG. 6G, a mask film 67 is then formed on the protective film 62, the magnetic region 65, and the magnetic region 66 by, for example, the photolithography method and the RIE method. This mask film 67 has an opening 67a formed at a position corresponding to a V_{high} node 32.

As shown in FIG. 6H, anisotropic etching is then carried out by, for example, the RIE method using the mask film 67 as a mask to remove the protective film 62 and the 2DEG channel precursor layer 60 in the opening 67a and part of the semiconductor substrate 10.

As shown in FIG. 6I, a second magnetic metal 68 is then formed in the opening 67a and on the protective film 62 by, for example, the CVD method. This second magnetic metal 68 is, for example, the above-mentioned Heuslar alloy.

As shown in FIG. 6J, planarization is then carried out by, for example, the CMP method to remove the second magnetic metal 68 on the protective film 62. As a result of the planarization, a magnetic region 69 comprising the second magnetic metal 68 is formed in the opening 67a.

As shown in FIG. 6K, the protective film 62 is then selectively removed by, for example, a wet etching method.

An insulating film is then deposited on the element isolation region 4, the semiconductor cap layer precursor layer 61, the magnetic region 65, the magnetic region 66, and the magnetic region 69 by, for example, the CVD method. As shown in FIG. 6L, isotropic etching is further carried out by, for example, the RIE method to form sidewalls 70 on the side surfaces of the magnetic region 65, the magnetic region 66, and the magnetic region 69.

As shown in FIG. 6M, a metal gate electrode precursor film 71 is then formed by, for example, the CVD method on the element isolation region 4, the semiconductor cap layer precursor layer 61, the magnetic region 65, the magnetic region 66, the magnetic region 69, and the sidewalls 70. This metal gate electrode precursor film 71 comprises a single layer made of a metal material such as Ta or Ru or comprises a structure in which metal materials are stacked. The stack structure is, for example, a stack structure including Ti/Au or a stack structure including TiN/Pt/Au.

As shown in FIG. 6N, gate masks 72 are then formed between the magnetic region 69 and the magnetic region 65 and between the magnetic region 65 and the magnetic region 66 by, for example, the photolithography method and the RIE method.

As shown in FIG. 6O and FIG. 5B, the metal gate electrode precursor film 71 is then removed by, for example, the RIE method using the gate masks 72 as masks. Here, the magnetic region 65 is used as the V_{low} node 22 of the integrated circuit 1. The magnetic region 66 is used as the output node 6. The magnetic region 69 is used as the V_{high} node 32. Further, magnetizations are formed in the V_{low} node 22, the output node 6, and the V_{high} node 32. A method of forming the magnetizations is described below.

(Regarding the Magnetization Forming Method)

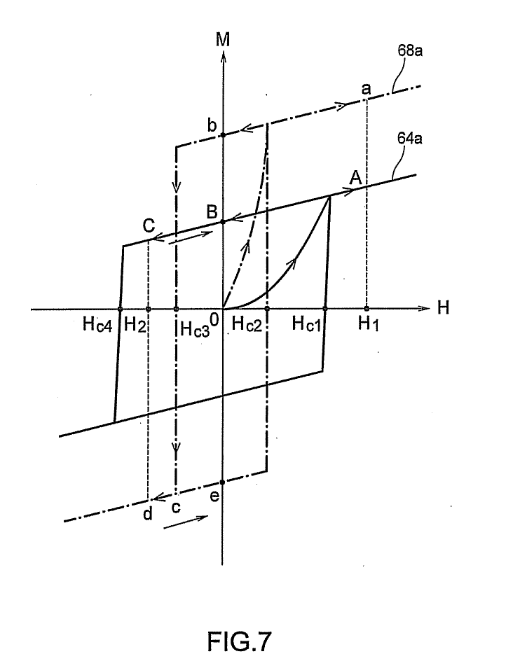

FIG. 7 is a schematic diagram of magnetization curves of a first magnetic metal and a second magnetic metal according to the third embodiment. The vertical axis in FIG. 7 indicates the intensity of magnetization M, and the horizontal axis indicates the intensity of a magnetic field H. A first magnetization curve 64a indicated by a solid line in FIG. 7 is a magnetization curve of the first magnetic metal 64, and a second magnetization curve 68a indicated by a one-dot chain line in FIG. 7 is a magnetization curve of the second magnetic metal 68. Magnetizations of the first magnetic metal 64 and the second magnetic metal 68 when an externally applied magnetic field H is changed in the order of O, H_{I}, O, H₂, and O are described below. The intensity of the magnetic field is H_{c4}<H₂<H_{c3}<0<H_{c2}<H_{c1}<H₁ when the right side of the magnetic field H in FIG. 7 is positive. The direction of the magnetic fields H₁, H_{c1}, and H_{c2} is opposite to the direction of the magnetic fields H_{c3}, H₂, and H_{c4}.

A point A indicated in FIG. 7 is a point on the first magnetization curve 64a in the magnetic field H₁. A point B is a point on the first magnetization curve 64a in a magnetic field zero. A point C is a point on the first magnetization curve 64a in the magnetic field H₂.

Furthermore, a point “a” indicated in FIG. 7 is a point on the second magnetization curve 68a in the magnetic field H₁. A point “b” and a point “e” are points on the second magnetization curve 68a when a magnetic body is magnetized in the magnetic field zero. A point “c” is a point on the second magnetization curve 68a in the magnetic field H_{c3}. A point d is a point on the second magnetization curve 68a in the magnetic field H₂.

First, the magnetic field H₁ is externally applied to the V_{low} node 22, the output node 6, and the V_{high} node 32 having zero magnetizations M. This external magnetic field is applied to the semiconductor substrate 10 in which, for example, the V_{low} node 22, the output node 6, and the V_{high} node 32 are formed.

The magnetization of the first magnetic metal 64 is described first. As shown in FIG. 7, along with the increase of the applied magnetic field from the magnetic field zero to the magnetic field H₁, the magnetization of the first magnetic metal 64 moves on an initial magnetization curve from a zero state, and increases to the point A on the first magnetization curve 64a in the magnetic field H₁.

When the applied magnetic field H₁ is brought to zero, the magnetization of the first magnetic metal 64 does not return on the initial magnetization curve from the point A, that is, does not become zero, and reaches the nonzero point B on the axis of the magnetization M. This point B on the axis of the magnetization M indicates the magnitude of remaining magnetization.

Along with the increase of the applied magnetic field from the magnetic field zero to the magnetic field H₂, the magnetization of the first magnetic metal 64 reaches the point C on the first magnetization curve 64a while the remaining magnetization gradually decreases but there is no inversion of the magnetization direction.

When the applied magnetic field H₂ is brought to zero, the magnetization of the first magnetic metal 64 gradually increases along the first magnetization curve 64a, and has remaining magnetization B in the magnetic field zero.

On the other hand, as shown in FIG. 7, along with the increase of the applied magnetic field from the magnetic field zero to the magnetic field H₁, the magnetization of the second magnetic metal 68 moves on an initial magnetization curve from a zero state, and increases to the point a on the first magnetization curve 64a in the magnetic field H₁. Here, magnetization M at the point a is higher than the magnetization M at the point A.

When the applied magnetic field H₁ is brought to zero, the magnetization of the second magnetic metal 68 does not return on the initial magnetization curve from the point “a”, and reaches the nonzero point “b” on the axis of the magnetization M. This point “b” on the axis of the magnetization M indicates the magnitude of remaining magnetization. Here, the remaining magnetization at the point “b” is higher than the remaining magnetization at the point B.

Along with the increase of the applied magnetic field from the magnetic field zero to the magnetic field H₂, the magnetization of the second magnetic metal 68 gradually reduces the remaining magnetization, and inverted in its direction and reaches the point “c” when the magnetic field is H_{c3}, and further reaches the point “d” at which the intensity of the magnetization is increased from the point “c”. The magnetization direction at the points “c” and “d” is opposite to the magnetization direction at the point B on the first magnetization curve 64a and at the point “b” on the second magnetization curve 68a.

When the applied magnetic field H₂ is brought to zero, the magnetization of the second magnetic metal 68 gradually decreases along the second magnetization curve 68a without being inverted in its direction, and has remaining magnetization “e” in the magnetic field zero.

Thus, by changing the applied magnetic field H in the order of 0, H₁, 0, H₂, and 0, magnetizations in opposite directions can be formed in the first magnetic metal 64 and the second magnetic metal 68 at the same time.

An integrated circuit 1 is then obtained through a known process. Although the magnetic field H is changed in the order of 0, H₁, 0, H₂, and 0 in the magnetization process described above, the magnetic field H may be changed in the order of 0, H₂, 0, H₁, and 0.

### Advantages of the Third Embodiment

In the integrated circuit 1 according to the third embodiment, the V_{low} node 22 and the output node 6 that have the same magnetization direction, and the V_{high} node 32 having a magnetization direction opposite to that of the V_{low} node 22 and the output node 6 can be magnetized at the same time. Therefore, as compared with the local magnetization, the processes are reduced, and the manufacturing costs of a semiconductor device comprising the integrated circuit 1 can be reduced.

### Fourth Embodiment

The fourth embodiment is different from the other embodiments described above in that the volume of a V_{high} node different in magnetization direction from a V_{low} node and an output node is different from the volumes of the V_{low} node and the output node.

Although the volume of a V_{high} node 32 is smaller than the volumes of a V_{low} node 22 and an output node 6 in the case described below, the present invention is not limited to this, and the volume of the V_{high} node 32 may be greater than the volumes of the V_{low} node 22 and the output node 6.

(Configuration of Integrated Circuit 1)

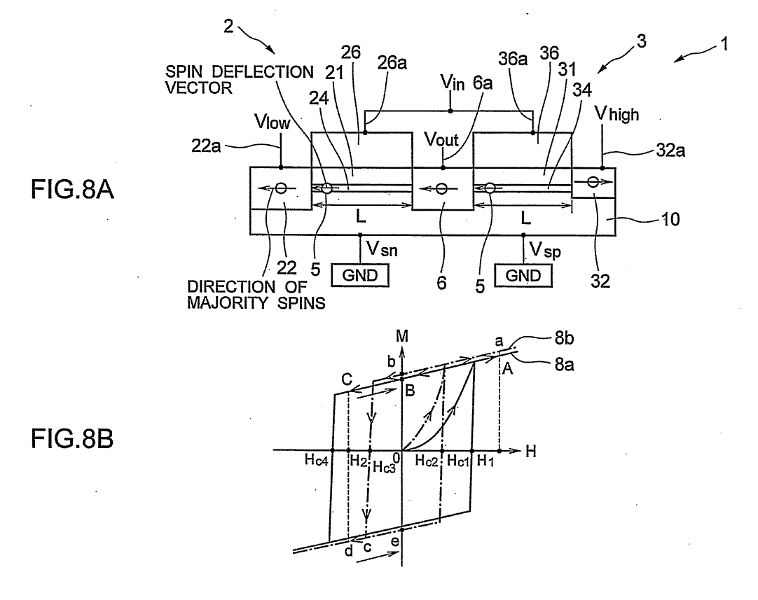

FIG. 8A is a schematic diagram of an integrated circuit according to the fourth embodiment. FIG. 8B is a schematic diagram of magnetization curves of magnetic metals. A first magnetization curve 8a indicated by a solid line in FIG. 8B is a magnetization curve of a magnetic metal constituting the V_{low} node 22 and the output node 6 that are greater in volume than the V_{high} node 32. A second magnetization curve 8b indicated by a one-dot chain line is a magnetization curve of a magnetic metal that constitutes the V_{high} node 32. Magnetization when an externally applied magnetic field H is changed in the order of 0, H₁, 0, H₂, and 0 as in the third embodiment is described below. The intensities of the magnetic fields are H_{c4}<H₂<H_{c3}<0<H_{c2}<H_{c1}<H₁ as in FIG. 7.

A point A indicated in FIG. 8B is a point on the first magnetization curve 8a in the magnetic field H₁. A point B is a point on the first magnetization curve 8a in a magnetic field zero. A point C is a point on the first magnetization curve 8a in the magnetic field H₂.

Furthermore, a point “a” indicated in FIG. 8B is a point on the second magnetization curve 8b in the magnetic field H₁. A point “b” and a point “e” are points on the second magnetization curve 8b in the magnetic field zero. A point “c” is a point on the second magnetization curve 8b in the magnetic field H_{c3}. A point “d” is a point on the second magnetization curve 8b in the magnetic field H₂.

An integrated circuit 1 according to the present embodiment has the same configuration as the integrated circuit according to the second embodiment except that the volume of the V_{high} node 32 of a second spin transistor 3 is smaller than the volumes of the V_{low} node 22 and the output node 6 that have a magnetization direction opposite to the magnetization direction of the V_{high} node 32. In addition, the V_{low} node 22, the output node 6, and the V_{high} node 32 are made of, for example, the same material.

The V_{high} node 32 is smaller in volume than the V_{low} node 22 and the output node 6, and as shown in FIG. 8B, the magnetic field intensity H_{c3} of the V_{high} node 32 at which its magnetization is inverted is lower than the magnetic field intensity H_{c4} at which the magnetizations of the V_{low} node 22 and the output node 6 are inverted. This is attributed to that fact that the magnetization is more easily inverted when the volume is smaller. Thus, by applying the magnetic field H₁ that reaches the magnetic saturation of a hysteresis loop through an initial magnetization curve and applying the magnetic field H₂ having a value between the values of the magnetic field H_{c3} and the magnetic field H_{c4}, the V_{low} node 22 and the output node 6 can be magnetized simultaneously with the magnetization of the V_{high} node 32 having a magnetization direction opposite to the magnetization directions of the V_{low} node 22 and the output node 6.

It should be noted that in the integrated circuit according to the first embodiment, one of magnetic regions (e.g. the output node 33) that is different in magnetization direction from the other may be different in volume from the other.

### Advantages of the Fourth Embodiment

In the integrated circuit 1 according to the fourth embodiment, the V_{low} node 22 different in magnetization direction from the V_{low} node and the output node can be magnetized simultaneously with the output node 6 and the V_{high} node 32. Therefore, as compared with the local magnetization dependent on the magnetization direction, the processes are reduced, and the manufacturing costs of a semiconductor device comprising the integrated circuit 1 can be reduced.

### Fifth Embodiment

The fifth embodiment is different from the other embodiments described above in that a magnetic body region is magnetized by using a wiring line formed above a spin transistor.

(Configuration of Integrated Circuit 1)

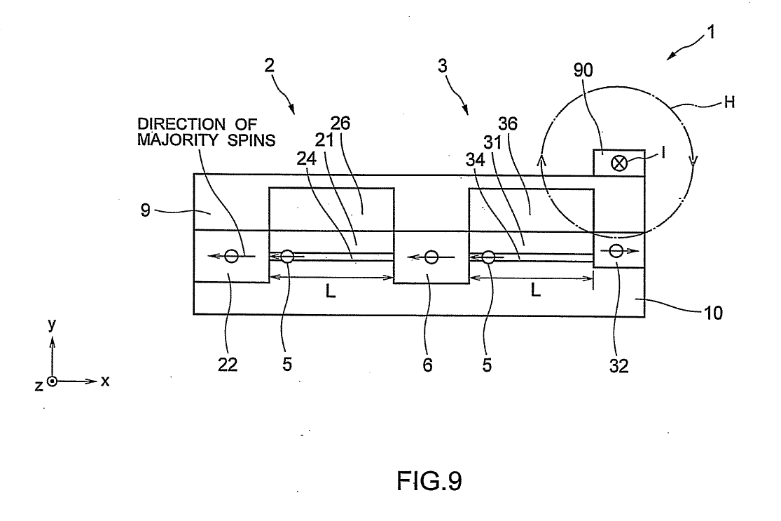

FIG. 9 is a schematic diagram of an integrated circuit according to the fifth embodiment. While the main configuration of an integrated circuit 1 according to the present embodiment is similar to the integrated circuit according to the fourth embodiment, an interlayer insulating film 9 is formed on a first spin transistor 2 and a second spin transistor 3, and a wiring line 90 is formed on the interlayer insulating film 9.

As has been shown in the fourth embodiment, a V_{high} node 32 is smaller in volume and thus in coercive force than a V_{low} node 22 and an output node 6. Therefore, as shown in FIG. 9, the wiring line 90 is formed above the V_{high} node 32. A current is passed through the wiring line 90 to generate a magnetic field H, and the V_{high} node 32 is magnetized by the magnetic field H. In addition, a wiring line may be provided above another magnetic body region, and the magnetic body region may be magnetized by passing a current through the wiring line.

### Advantages of the Fifth Embodiment

The integrated circuit 1 according to the fifth embodiment comprises the wiring line above the magnetic body region, so that the magnetic body region can be magnetized even after a semiconductor device is manufactured. In the integrated circuit 1, even if magnetization is inverted or disappears, for example, due to an external disturbing magnetic field or temperature fluctuations, a current is passed through the wiring line located above the defective magnetic body region, and a magnetic field thus generated can again magnetize the magnetic body region even after a semiconductor device has been manufactured. Moreover, the integrated circuit 1 can prevent a problem such as the disappearance of magnetization, for example, by periodically passing a current through the wiring line.

### Sixth Embodiment

The sixth embodiment is different from the other embodiments described above in that the spin transistors described above are combined to constitute a NAND circuit.

(Configuration of NAND Circuit 100a)

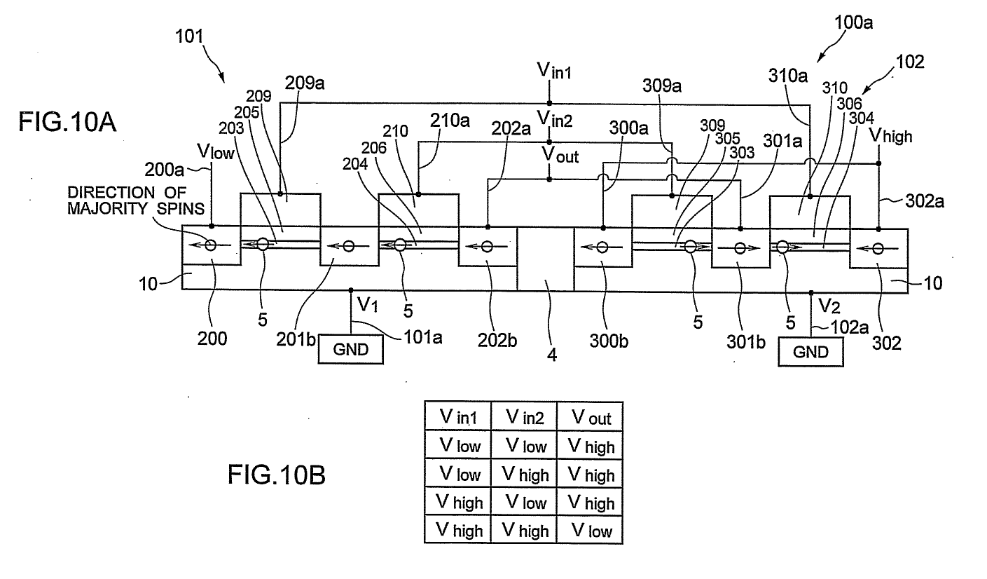

FIG. 10A is a schematic diagram of a NAND circuit according to the sixth embodiment. FIG. 10B is a logical operation table of the NAND circuit. In a NAND circuit 100a according to the present embodiment, a first element 101 and a second element 102 comprising spin transistors that are located across an element isolation region 4 are connected to each other in series between a power supply voltage V_{low} and a power supply voltage V_{high}.

As shown in FIG. 10A, in the first element 101, a V_{low} node 200, an intermediate node 201b, and an output node 202b are formed side by side on a semiconductor substrate 10 so that the channel length of each node is L. A 2DEG channel 203 is formed between the V_{low} node 200 and the intermediate node 201b, and a 2DEG channel 204 is formed between the intermediate node 201b and the output node 202b. The V_{low} node 200, the intermediate node 201b, and the output node 202b have the same majority spin direction.

A gate electrode 209 is formed above the 2DEG channel 203 across a semiconductor cap layer 205.

A gate electrode 210 is formed above the 2DEG channel 204 across a semiconductor cap layer 206.

The V_{low} node 200 has a terminal 200a, and the power supply voltage V_{low} is supplied to the terminal 200a from a power supply circuit. The output node 202b has a terminal 202a.

The gate electrode 209 has a terminal 209a. The gate electrode 210 has a terminal 210a.

A terminal 101a is formed in the semiconductor substrate 10 of the first element 101. A substrate potential V₁ of the first element 101 is, by way of example, grounded and is therefore 0 V.

As shown in FIG. 10A, in the second element 102, a V_{high} node 300b, an output node 301b, and a V_{high} node 302 are formed side by side on the semiconductor substrate 10 so that the channel length of each node is L. A 2DEG channel 303 is formed between the V_{high} node 300b and the output node 301b, and a 2DEG channel 304 is formed between the output node 301b and the V_{high} node 302.

A gate electrode 309 is formed above the 2DEG channel 303 across a semiconductor cap layer 305.

A gate electrode 310 is formed above the 2DEG channel 304 across a semiconductor cap layer 306.

The V_{high} node 300b has a terminal 300a. The output node 301b has a terminal 301a, is connected to the terminal 202a of the output node 202b of the first element 101, and outputs Vₒᵤₜ. The V_{high} node 302 has a terminal 302a, and the power supply voltage V_{high} is supplied to the terminal 302a from the power supply circuit. This terminal 302a is connected to the terminal 300a of the V_{high} node 300b. That is, the V_{high} node 300b and the V_{high} node 302 have the same potential. A substrate potential V₂ of the second element 102 is, by way of example, grounded and is therefore 0 V.

The V_{high} node 300b and the V_{high} node 302 have the same majority spin direction. The majority spin direction of the output node 301b is opposite to the majority spin direction of the V_{high} node 300b and the V_{high} node 302. According to the present embodiment, the majority spin direction of the V_{high} node 300b and the V_{high} node 302 of the second element 102 and the majority spin direction of the V_{low} node 200, the intermediate node 201b, and the output node 202b of the first element 101 are, but not exclusively, the same, and may be opposite to each other. In this case, the majority spin direction of the output node 301b is the same as the majority spin direction of the V_{low} node 200, the intermediate node 201b, and the output node 202b.

The gate electrode 309 has a terminal 309a. This terminal 309a is connected to the terminal 210a of the gate electrode 210 of the first element 101, and a digital signal Vᵢₙ₂ is input to the terminal 309a. The gate electrode 310 has a terminal 310a. This terminal 310a is connected to the terminal 209a of the gate electrode 209 of the first element 101, and a digital signal Vᵢₙ₁ is input to the terminal 310a.

A terminal 102a is formed in the semiconductor substrate 10 of the second element 102.

The operation of the NAND circuit 100a is described below with reference to the logical operation table shown in FIG. 10B.

(Operation)

Hereinafter, when the voltage V_{low} is applied to the gate electrode, an electron 5 traveling through the 2DEG channel having the channel length L precesses, for example, at an angle π. When the voltage V_{high} is applied to the gate electrode, an electron 5 traveling through the 2DEG channel having the channel length L precesses, for example, at an angle 2π.

(When Vᵢₙ₁=V_{low} and Vᵢₙ₂=V_{low})

First, V_{low} is input as Vᵢₙ₁ to the gate electrode 209 of the first element 101 and to the gate electrode 310 of the second element 102. V_{low} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle π around the z axis due to an effective magnetic field in the 2DEG channel 203, and reaches the border between the 2DEG channel 203 and the intermediate node 201b.

The electron 5 which has reached the border has a spin direction that differs by an angle π from the majority spin direction of the intermediate node 201b, and is therefore reflected at the border. That is, the electron 5 cannot penetrate the intermediate node 201b, so that no current runs through the first element 101.

On the other hand, a spin-polarized electron 5 is injected into the 2DEG channel 303 and the 2DEG channel 304 from the output node 301b of the second element 102.

This electron 5 precesses, for example, at an angle π/2 around the z axis due to an effective magnetic field in the 2DEG channel 303, and reaches the border between the 2DEG channel 303 and the V_{high} node 300b.

The electron 5 which has reached the border has a spin direction that is the same as the majority spin direction of the V_{high} node 300b, and therefore penetrates the border. This is due to the fact that the majority spin direction of the V_{high} node 300b differs from the majority spin direction of the output node 301b by an angle π.

An electron 5 also precesses, for example, at an angle π around the z axis due to an effective magnetic field in the 2DEG channel 304, and reaches the border between the 2DEG channel 304 and the V_{high} node 302.

The electron 5 which has reached the border has a spin direction that differs by an angle π from the majority spin direction of the V_{high} node 302, and therefore penetrates the border. That is, the potential of the output node 301b is V_{high}.

Accordingly, in the integrated circuit 1, when Vᵢₙ₁=V_{low} and Vᵢₙ₂=V_{low}, no current runs through the first element 101, and a current runs through the second element 102, so that V_{high} is output from Vₒᵤₜ.

(When Vᵢₙ₁=V_{low} and Vᵢₙ₂=V_{high})

First, V_{low} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle π around the z axis due to an effective magnetic field in the 2DEG channel 203, and reaches the border between the 2DEG channel 203 and the intermediate node 201b.

The electron 5 which has reached the border has a spin direction that differs by an angle π from the majority spin direction of the intermediate node 201b, and is therefore reflected at the border. That is, the electron 5 cannot penetrate the intermediate node 201b, so that no current runs through the first element 101.

On the other hand, a spin-polarized electron 5 is injected into the 2DEG channel 303 and the 2DEG channel 304 from the output node 301b of the second element 102.

This electron 5 precesses, for example, at an angle 2π around the z axis due to an effective magnetic field in the 2DEG channel 303, and reaches the border between the 2DEG channel 303 and the V_{high} node 300b.

The electron 5 which has reached the border has a spin direction opposite to the majority spin direction of the V_{high} node 300b, and is therefore reflected at the border.

An electron 5 also precesses, for example, at an angle π around the z axis due to an effective magnetic field in the 2DEG channel 304, and reaches the border between the 2DEG channel 304 and the V_{high} node 302.

The electron 5 which has reached the border has a spin direction that is the same as the majority spin direction of the V_{high} node 302, and therefore penetrates the border. That is, the potential of the output node 301b is V_{high}.

Accordingly, in the integrated circuit 1, when Vᵢₙ₁⁼V_{low} and Vᵢₙ₂=V_{low}, no current runs through the first element 101, and a current runs through the second element 102, so that V_{high} is output from Vₒᵤₜ.

(When Vᵢₙ₁=V_{high} and Vᵢₙ₂=V_{low})

First, V_{high} is input as Vᵢₙ₁ to the gate electrode 209 of the first element 101 and to the gate electrode 310 of the second element 102. V_{low} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle 2π around the z axis due to an effective magnetic field in the 2DEG channel 203, and reaches the border between the 2DEG channel 203 and the intermediate node 201b.

The electron 5 which has reached the border has a spin direction that differs by an angle 2π from the majority spin direction of the intermediate node 201b, and penetrates the border.

Furthermore, a spin-polarized electron 5 is injected into the 2DEG channel 204 from the intermediate node 201b of the first element 101.

This electron 5 precesses, for example, at an angle π around the z axis due to an effective magnetic field in the 2DEG channel 204, and reaches the border between the 2DEG channel 204 and the output node 202b.

The electron 5 which has reached the border has a spin direction that differs by an angle π from the majority spin direction of the output node 202b, and is therefore reflected at the border. That is, no current runs through the first element 101.

On the other hand, a spin-polarized electron 5 is injected into the 2DEG channel 303 and the 2DEG channel 304 from the output node 301b of the second element 102.

This electron 5 precesses, for example, at an angle π around the z axis due to an effective magnetic field in the 2DEG channel 303, and reaches the border between the 2DEG channel 303 and the V_{high} node 300b.

The electron 5 which has reached the border has a spin direction that is the same as the majority spin direction of the V_{high} node 300b, and therefore penetrates the border.

An electron 5 also precesses, for example, at an angle 2π around the z axis due to an effective magnetic field in the 2DEG channel 304, and reaches the border between the 2DEG channel 304 and the V_{high} node 302.

The electron 5 which has reached the border has a spin direction opposite to the majority spin direction of the V_{high} node 302, and is therefore reflected at the border. However, a current runs across the output node 301b and the V_{high} node 300b, so that the potential of the output node 301b is V_{high}.

Accordingly, in the integrated circuit 1, when Vᵢₙ₁=V_{high} and Vᵢₙ₂=V_{low}, no current runs through the first element 101, and a current runs across the output node 301b and the V_{high} node 302 of the second element 102, so that V_{high} is output from Vₒᵤₜ.

(When Vᵢₙ₁=V_{high} and Vᵢₙ₂=V_{high})

First, V_{high} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle 2π around the z axis due to an effective magnetic field in the 2DEG channel 203, and reaches the border between the 2DEG channel 203 and the intermediate node 201b.

The electron 5 which has reached the border has a spin direction that differs by an angle 2π from the majority spin direction of the intermediate node 201b, and therefore penetrates the border.

Furthermore, a spin-polarized electron 5 is injected into the 2DEG channel 204 from the intermediate node 201b of the first element 101.

This electron 5 precesses, for example, at an angle 2π around the z axis due to an effective magnetic field in the 2DEG channel 204, and reaches the border between the 2DEG channel 204 and the output node 202b.

The electron 5 which has reached the border has a spin direction that differs by an angle 2π from the majority spin direction of the output node 202b, and therefore penetrates the border. That is, the potential of the output node 202b is V_{low}.

On the other hand, a spin-polarized electron 5 is injected into the 2DEG channel 303 and the 2DEG channel 304 from the output node 301b of the second element 102.

This electron 5 precesses, for example, at an angle 2π around the z axis due to an effective magnetic field in the 2DEG channel 303, and reaches the border between the 2DEG channel 303 and the V_{high} node 300b.

The electron 5 which has reached the border has a spin direction opposite to the majority spin direction of the V_{high} node 300b, and is therefore reflected at the border.

An electron 5 also precesses, for example, at an angle 2π around the z axis due to an effective magnetic field in the 2DEG channel 304, and reaches the border between the 2DEG channel 304 and the V_{high} node 302.

The electron 5 which has reached the border has a spin direction opposite to the majority spin direction of the V_{high} node 302, and is therefore reflected at the border. That is, no current runs through the second element 102.

Accordingly, in the integrated circuit 1, when Vᵢₙ₁=V_{high} and Vᵢₙ₂=V_{high}, a current runs through the first element 101, and no current runs through the second element 102, so that V_{low} is output from Vₒᵤₜ.

Consequently, the NAND circuit 100a satisfies the logical operation table shown in FIG. 10B, and therefore comprises a NAND circuit.

### Advantages of the Sixth Embodiment

As compared with a NAND circuit which comprises a CMOS transistor, the NAND circuit 100a according to the sixth embodiment does not need separate p-type and n-type transistors, leading to fewer manufacturing processes and reduced manufacturing costs.

### Seventh Embodiment

The seventh embodiment is different from the other embodiments described above in that the spin transistors described above are combined to constitute a NOR circuit.

(Configuration of NOR Circuit 100b)

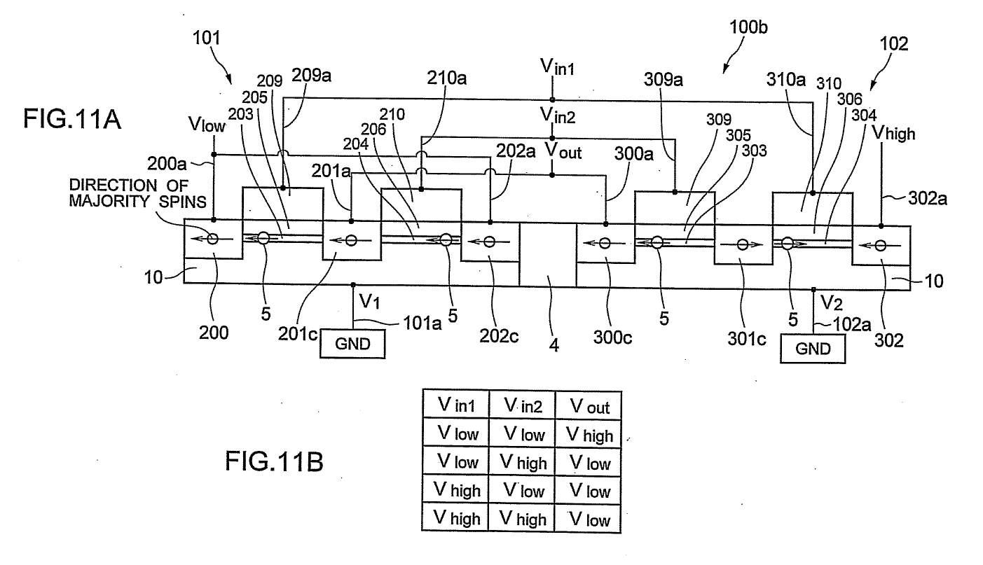

FIG. 11A is a schematic diagram of a NOR circuit according to the seventh embodiment. FIG. 11B is a logical operation table of the NOR circuit. The basic configuration of a NOR circuit 100b according to the present embodiment is the same as that of the NAND circuit 100a according to the sixth embodiment. However, the NOR circuit 100b is different from the NAND circuit 100a in the connection of terminals. In the present embodiment, the differences between the sixth embodiment and the seventh embodiment are mainly described.

As shown in FIG. 11A, in a first element 101, a power supply voltage V_{low} is supplied to a V_{low} node 200 from a power supply circuit. A terminal 200a of the V_{low} node 200 is connected to a terminal 202a of a V_{low} node 202c. A terminal 201a of an output node 201c is connected to a terminal 300a of an output node 300c of a second element 102. A substrate potential V₁ of the first element 101 is, by way of example, grounded and is therefore 0 V.

In the second element 102, a power supply voltage V_{high} is supplied to a V_{high} node 302 from the power supply circuit. In the second element 102, the V_{high} node 302 and the output node 300c have the same magnetization direction. An intermediate node 301c formed between the V_{high} node 302 and the output node 300c has a magnetization direction opposite to the magnetization directions of the V_{high} node 302 and the output node 300c. A substrate potential V₂ of the second element 102 is, by way of example, grounded and is therefore 0 V.

The operation of the NOR circuit 100b is described below with reference to the logical operation table shown in FIG. 11B.

(Operation)

(When Vᵢₙ₁=V_{low} and Vᵢₙ₂=V_{low})

First, V_{low} is input as Vᵢₙ₁ to a gate electrode 209 of the first element 101 and to a gate electrode 310 of the second element 102. V_{low} is also input as Vᵢₙ₂ to a gate electrode 210 of the first element 101 and to a gate electrode 309 of the second element 102.

A spin-polarized electron 5 is injected into a 2DEG channel 203 from the V_{low} node 200 of the first element 101.

This electron 5 precesses, for example, at an angle π around the z axis due to an effective magnetic field in the 2DEG channel 203, and reaches the border between the 2DEG channel 203 and the output node 201c.

The electron 5 which has reached the border has a spin direction that differs by an angle π from the majority spin direction of the output node 201c, and is therefore reflected at the border.

A spin-polarized electron 5 is also injected into a 2DEG channel 204 from the V_{low} node 202c of the first element 101.

This electron 5 precesses, for example, at an angle π around the z axis due to an effective magnetic field in the 2DEG channel 204, and reaches the border between the 2DEG channel 204 and the output node 202c.

The electron 5 which has reached the border has a spin direction that differs by an angle π from the majority spin direction of the output node 201c, and is therefore reflected at the border. That is, no current runs through the first element 101.

On the other hand, a spin-polarized electron 5 is injected into a 2DEG channel 303 from the output node 300c of the second element 102.

This electron 5 precesses, for example, at an angle π around the z axis due to an effective magnetic field in the 2DEG channel 303, and reaches the border between the 2DEG channel 303 and an intermediate node 301c.

The electron 5 which has reached the border has a spin direction that is the same as the majority spin direction of the intermediate node 301c, and therefore penetrates the border.

Furthermore, a spin-polarized electron 5 is injected into a 2DEG channel 304 from the intermediate node 301c of the second element 102.

This electron 5 precesses, for example, at an angle π around the z axis due to an effective magnetic field in the 2DEG channel 304, and reaches the border between the 2DEG channel 304 and the V_{high} node 302.

The electron 5 which has reached the border has a spin direction that is the same as the majority spin direction of the V_{high} node 302, and therefore penetrates the border. That is, the potential of the output node 300c is V_{high}.

Accordingly, in the integrated circuit 1, when Vᵢₙ₁=V_{low} and Vᵢₙ₂=V_{low}, no current runs through the first element 101, and a current runs through the second element 102, so that V_{high} is output from Vₒᵤₜ.

(When Vᵢₙ₁=V_{low} and Vᵢₙ₂=V_{high})

First, V_{low} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle π around the z axis due to an effective magnetic field in the 2DEG channel 203, and reaches the border between the 2DEG channel 203 and the output node 201c.

The electron 5 which has reached the border has a spin direction that differs by an angle π from the majority spin direction of the output node 201c, and is therefore reflected at the border.

A spin-polarized electron 5 is also injected into the 2DEG channel 204 from the V_{low} node 202c of the first element 101.

This electron 5 precesses, for example, at an angle 2π around the z axis due to an effective magnetic field in the 2DEG channel 204, and reaches the border between the 2DEG channel 204 and the output node 201c.

The electron 5 which has reached the border has a spin direction that differs by an angle 2π from the majority spin direction of the output node 201c, and therefore penetrates the border. That is, the potential of the output node 201c is V_{low}.

On the other hand, a spin-polarized electron 5 is injected into the 2DEG channel 303 from the output node 300c of the second element 102.

This electron 5 precesses, for example, at an angle 2π around the z axis due to an effective magnetic field in the 2DEG channel 303, and reaches the border between the 2DEG channel 303 and the intermediate node 301c.

The electron 5 which has reached the border has a spin direction opposite to the majority spin direction of the intermediate node 301c, and is therefore reflected at the border. Thus, no current runs through the second element 102.

Accordingly, in the integrated circuit 1, when Vᵢₙ₁=V_{low} and Vᵢₙ₂=V_{high}, a current runs through the first element 101, and no current runs through the second element 102, so that V_{low} is output from Vₒᵤₜ.

(When Vᵢₙ₁=V_{high} and Vᵢₙ₂=V_{low})

First, V_{high} is input as Vᵢₙ₁ to the gate electrode 209 of the first element 101 and to the gate electrode 310 of the second element 102. V_{low} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle 2π around the z axis due to an effective magnetic field in the 2DEG channel 203, and reaches the border between the 2DEG channel 203 and the output node 201c.

The electron 5 which has reached the border has a spin direction that differs by an angle 2π from the majority spin direction of the output node 201c, and therefore penetrates the border.

A spin-polarized electron 5 is also injected into the 2DEG channel 204 from the V_{low} node 202c of the first element 101.

This electron 5 precesses, for example, at an angle π around the z axis due to an effective magnetic field in the 2DEG channel 204, and reaches the border between the 2DEG channel 204 and the V_{low} node 202c.

The electron 5 which has reached the border has a spin direction that differs by an angle π from the majority spin direction of the output node 201c, and is therefore reflected at the border. However, a current runs across the V_{low} node 200 and the output node 201c, so that the potential of the output node 201c is V_{low}.

On the other hand, a spin-polarized electron 5 is injected into the 2DEG channel 303 from the output node 300c of the second element 102.

This electron 5 precesses, for example, at an angle π around the z axis due to an effective magnetic field in the 2DEG channel 303, and reaches the border between the 2DEG channel 303 and the intermediate node 301c.

The electron 5 which has reached the border has a spin direction that is the same as the majority spin direction of the intermediate node 301c, and therefore penetrates the border.

Furthermore, a spin-polarized electron 5 is injected into the 2DEG channel 304 from the intermediate node 301c of the second element 102.

This electron 5 precesses, for example, at an angle 2π around the z axis due to an effective magnetic field in the 2DEG channel 304, and reaches the border between the 2DEG channel 304 and the V_{high} node 302.

The electron 5 which has reached the border has a spin direction opposite to the majority spin direction of the V_{high} node 302, and is therefore reflected at the border. Thus, no current runs through the second element 102.

Accordingly, in the integrated circuit 1, when Vᵢₙ₁=V_{high} and Vᵢₙ₂=V_{low}, a current runs through the first element 101, and no current runs through the second element 102, so that V_{low} is output from Vₒᵤₜ.

(When Vᵢₙ₁=V_{high} and Vᵢₙ₂=V_{high})

First, V_{high} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2DEG channel 203 from the V_{low} node 200 of the first element 101.

This electron 5 precesses, for example, at an angle 2π around the z axis due to an effective magnetic field in the 2DEG channel 203, and reaches the border between the 2DEG channel 203 and the output node 201c.

The electron 5 which has reached the border has a spin direction that differs by an angle 2π from the majority spin direction of the output node 201c, and therefore penetrates the border.

A spin-polarized electron 5 is also injected into the 2DEG channel 204 from the V_{low} node 202c of the first element 101.

This electron 5 precesses, for example, at an angle 2π around the z axis due to an effective magnetic field in the 2DEG channel 204, and reaches the border between the 2DEG channel 204 and the output node 201c.

The electron 5 which has reached the border has a spin direction that differs by an angle 2π from the majority spin direction of the output node 201c, and therefore penetrates the border. That is, the potential of the output node 201c is V_{low}.

On the other hand, a spin-polarized electron 5 is injected into the 2DEG channel 303 from the output node 300c of the second element 102.

This electron 5 precesses, for example, at an angle 2π around the z axis due to an effective magnetic field in the 2DEG channel 303, and reaches the border between the 2DEG channel 303 and the intermediate node 301c.

The electron 5 which has reached the border has a spin direction opposite to the majority spin direction of the intermediate node 301c, and is therefore reflected at the border. Thus, no current runs through the second element 102.

Accordingly, in the integrated circuit 1, when Vᵢₙ₁=V_{high} and Vᵢₙ₂=V_{high}, a current runs through the first element 101, and no current runs through the second element 102, so that V_{low} is output from Vₒᵤₜ.

Consequently, the NOR circuit 100a satisfies the logical operation table shown in FIG. 11B, and therefore comprises a NOR circuit.

### Advantages of the Seventh Embodiment

As compared with a NOR circuit which comprises a CMOS transistor, the NOR circuit 100b according to the seventh embodiment does not need separate p-type and n-type transistors, leading to fewer manufacturing processes and reduced manufacturing costs.

According to the embodiments described above, a logical operation circuit can be formed by using a spin transistor which comprises a node as a source region and a node as a drain region that have the same magnetization direction, and a spin transistor which comprises a node as a source region and a node as a drain region that have opposite magnetization directions.

Moreover, according to the embodiments described above, each node is formed by a ferromagnetic body. This makes it possible to prevent, for example, a short channel effect such as a gate leakage and drain induced-barrier lowering (DIBL), and gate induced drain leakage (GIDL) caused by inhibiting the short channel effect. In the integrated circuit 1 according to each of the embodiments, the width of V_{high} and V_{low} for switching on/off the first and second spin transistors 2 and 3 can be small, so that power consumption is low.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An integrated circuit comprising:
a circuit in which first and second spin transistors are connected in series,
the first spin transistor comprising a first node and a second node that are equal to each other in magnetization direction,
the second spin transistor comprising a third node and a fourth node that are opposite to each other in magnetization direction,
wherein the second node and the fourth node are electrically connected to each other.

2. The circuit of claim 1,
wherein the first spin transistor comprises a first gate electrode,
the second spin transistor comprises a second gate electrode,
the first node is supplied with a first voltage,
the third node is supplied with a second voltage,
the first and second gate electrodes are electrically connected to each other.

3. The circuit of claim 1,
wherein the first to fourth nodes are formed by use of a high spin deflection material.

4. The circuit of claim 3,
wherein the high spin deflection material is a ferromagnetic metal.

5. The circuit of claim 3,
wherein the nodes of the first and second spin transistors are made of a ferromagnetic body, the ferromagnetic body being consistent with a group III-V semiconductor, having a Curie temperature equal to or more than a room temperature, and having a wide band gap in the vicinity of a Fermi level E_{F} regarding the energy state of one spin, and
the ferromagnetic body is a half metal ferromagnetic body comprising a band structure in which the Fermi level E_{F} traverses one spin band and traverses the band gap in the other spin band.

6. The circuit of claim 1,
wherein both a substrate of the first spin transistor and a substrate of the second spin transistor are grounded.

7. The circuit of claim 1,
wherein materials of the first to fourth nodes are the same.

8. The circuit of claim 1,
wherein the first and second spin transistors have the same channel length.

9. The circuit of claim 2,
wherein a material of the first gate electrode is the same as a material of the second gate electrode.

10. The circuit of claim 1, wherein
the second node and the fourth node are the same region.

11. The circuit of claim 10, wherein
the third node has a volume different from the volumes of the first node and the same region.

12. The circuit of claim 1,
wherein a material of one of nodes that is different in magnetization direction from the other is different from a material of the other.

13. The circuit of claim 12,
wherein the different material comprises NiFe having a different doping ratio.

14. The circuit of claim 1,
wherein one of the third node and the fourth node that has a magnetization direction opposite to the magnetization directions of the first node and the second node has a volume different from the volumes of the first node and the second node, and
one of the third node and the fourth node that has the same magnetization direction as the magnetization directions of the first node, and the second node has the same volume as the first node and the second node.

15. The circuit of claim 14, further comprising
a wiring line provided above the first and second spin transistors via an insulating film, a current to magnetize the nodes running through the wiring line.

16. The circuit of claim 1,
wherein the first spin transistor comprises a fifth node between the first node and the second node, a first channel region between the first node and the fifth node, a first gate electrode above the first channel, a second channel region between the fifth node and the second node, and a second gate electrode above the second channel,
the second spin transistor comprises a sixth node apart from the fourth node on the side opposite the third node, a third channel region between the third node and the fourth node, a third gate electrode above the third channel region, a fourth channel region between the fourth node and the sixth node, and a fourth gate electrode above the fourth channel,
the first node is supplied with a first voltage,
the third node is supplied with a second voltage,
the first and third gate electrodes are electrically connected to each other,
the second and fourth gate electrodes are electrically connected to each other,
the third and sixth nodes are electrically connected to each other, and
a substrate potential of the first spin transistor and a substrate potential of the second spin transistor are the same.

17. The circuit of claim 16,
wherein the first to fourth channel regions have the same channel length.

18. The circuit of claim 1,
wherein the first spin transistor comprises a fifth node apart from the second node on the side opposite the first node, a first channel region between the first node and the second node, a first gate electrode above the first channel, a second channel region between the second node and the fifth node, and a second gate electrode above the second channel region,
the second spin transistor comprises a sixth node between the third node and the fourth node, a third channel region between the third node and the sixth node, a third gate electrode above the third channel region, a fourth channel region between the fourth node and the sixth node, and a fourth gate electrode above the fourth channel region,
the first node is supplied with a first voltage,
the third node is supplied with a second voltage,
the first and third gate electrodes are electrically connected to each other,
the second and fourth gate electrodes are electrically connected to each other,
the first and fifth nodes are electrically connected to each other, and
a substrate potential of the first spin transistor and a substrate potential of the second spin transistor are the same.

19. The circuit of claim 18,
wherein the first to fourth channel regions have the same channel length.

20. The circuit of claim 19,
wherein both a substrate of the first spin transistor and a substrate of the second spin transistor are grounded.
